(19) United States
(12) Patent Application Publication
(10) Pub. No.: US 2025/0040269 A1
(43) Pub. Date: Jan. 30, 2025

(54) PHOTODETECTION DEVICE AND DISTANCE MEASURING SYSTEM

(71) Applicant: SONY SEMICONDUCTOR SOLUTIONS CORPORATION, KANAGAWA (JP)

(72) Inventors: TATSUKI NISHINO, KANAGAWA (JP); SHUNPEI SUZUKI, KANAGAWA (JP)

(21) Appl. No.: 18/575,188

(22) PCT Filed: Mar. 31, 2022
(86) PCT No.: PCT/JP2022/016794

§ 371 Date: Dec. 28, 2023

(30) Foreign Application Priority Data
Jul. 12, 2021 (JP) 2021-115209

(51) Int. Cl. H01L 27/146; G01S 7/481; G01S 7/4865; G01S 17/10

(52) U.S. Cl. CPC H01L 27/14605; G01S 7/4814; G01S 7/4816; G01S 7/4865; G01S 17/10; H01L 27/1462; H01L 27/14623; H01L 27/14627

(57) ABSTRACT

There is provided a photodetection device capable of widening a dynamic range without increasing the number of photoelectric converters. The photodetection device according to an embodiment of the present disclosure includes a plurality of photoelectric converters arranged in one of pixels and configured to photoelectrically convert incident light. The plurality of photoelectric converters includes at least one first photoelectric converter and at least one second photoelectric converter having a lower sensitivity to the incident light than the first photoelectric converter.

### TECHNICAL FIELD

The present disclosure relates to a photodetection device and a distance measuring system.

### BACKGROUND ART

A time of flight (ToF) method is used for measuring the distance to the object. In the ToF method, light emitted from a light source is reflected by an object, and the reflected light is photoelectrically converted. Subsequently, the distance to the object is measured on the basis of the time from the emission of the light to the photoelectric conversion of the reflected light.

A distance measuring system using the ToF method is generally provided with a photodetection device that photoelectrically converts the reflected light described above. Some photodetection devices are provided with a plurality of photoelectric converters in one of pixels. In such a photodetection device, increasing the number of photoelectric converters per pixel widens the dynamic range. On the other hand, it is expected that the chip size and the power consumption increase.

### CITATION LIST

### Patent Document

Patent Document 1: Japanese Patent Application Laid-Open No. 2019-190892

### SUMMARY OF THE INVENTION

### Problems to be Solved by the Invention

The present disclosure provides a photodetection device and a distance measuring system capable of widening a dynamic range without increasing the number of photoelectric converters.

### Solutions to Problems

The photodetection device according to an embodiment of the present disclosure includes a plurality of photoelectric converters arranged in one of pixels and configured to photoelectrically convert incident light. The plurality of photoelectric converters includes at least one first photoelectric converter and at least one second photoelectric converter having a lower sensitivity to the incident light than the first photoelectric converter.

Each sensitivity may be different from others among the plurality of second photoelectric converters.

The number of second photoelectric converters may be smaller than the number of first photoelectric converters.

Each of the first photoelectric converters may include a first avalanche photodiode, and each of the second photoelectric converters may include a second avalanche photodiode.

A first voltage applied to the first avalanche photodiode may be different from a second voltage applied to the second avalanche photodiode.

In a case where the first voltage is applied to a cathode of the first avalanche photodiode and the second voltage is applied to a cathode of the second avalanche photodiode, the second voltage may be lower than the first voltage.

In a case where the first voltage is applied to an anode of the first avalanche photodiode and the second voltage is applied to an anode of the second avalanche photodiode, the second voltage may be higher than the first voltage.

The photodetection device may further include a voltage-adjusting unit that is configured to adjust the first voltage to the second voltage.

Opening ratios of the second photoelectric converters may be smaller than an opening ratio of the first photoelectric converters.

A light-shielding region from the incident light in each of the second photoelectric converters may be wider than a light-shielding region from the incident light in the first photoelectric converters.

The photodetection device may further include a light-shielding film provided in the light-shielding region.

Furthermore, another photodetection device according to an embodiment of the present disclosure includes a plurality of photoelectric converters arranged in one of pixels and configured to photoelectrically convert incident light. Sensitivities of the plurality of photoelectric converters to the incident light are configured to be collectively decreased in a stepwise manner depending on a result of photoelectric conversions at the plurality of photoelectric converters.

In a case where all of the plurality of photoelectric converters photoelectrically convert the incident light, the sensitivities may be configured to be collectively decreased in a stepwise manner.

The photodetection device may further include a switch connected to a plurality of external power supplies having different output voltages from each other, in which
the switch is configured to switch a voltage to be applied to the plurality of photoelectric converters from an output voltage of an external power supply of the plurality of external power supplies to an output voltage of another external power supply depending on a result of photoelectric conversions at the plurality of photoelectric converters.

Each of the plurality of photoelectric converters may include an avalanche photodiode, a transistor connected to the avalanche photodiode, and a switch connected in parallel to the transistor, in which
the switch is configured to be turned on and off depending on a result of a photoelectric conversion at the avalanche photodiode.

The photodetection device may further include:
a light-receiving lens that focuses the incident light on the plurality of photoelectric converters; and
an optical film that is provided on a surface of the light-receiving lens and is configured to attenuate the incident light depending on a set value of the sensitivity.

The sensitivity of the first photoelectric converters may be 10 times or more higher than the sensitivities of the second photoelectric converters.

A distance measuring system according to an embodiment of the present disclosure includes: a photodetection device including a plurality of photoelectric converters arranged in one of pixels and configured to photoelectrically convert incident light, in which the plurality of photoelectric converters includes: at least one first photoelectric converter; and at least one second photoelectric converter having a lower sensitivity to the incident light than the first photoelectric converter; and a signal processing circuit that processes an output signal of the photodetection device.

Another distance measuring system according to an embodiment of the present disclosure includes:
a photodetection device including a plurality of photoelectric converters arranged in one of pixels and configured to photoelectrically convert incident light, in which sensitivities of the plurality of photoelectric converters to the incident light are configured to be collectively decreased in a stepwise manner depending on a result of photoelectric conversions at the plurality of photoelectric converters; and
a signal processing circuit that processes an output signal of the photodetection device.

### BRIEF DESCRIPTION OF DRAWINGS

FIG. 1 is a diagram for explaining a distance measuring method by a distance measuring system according to a first embodiment.

FIG. 2 is a block diagram illustrating an example of a configuration of the distance measuring system.

FIG. 3 is a schematic plan view of a photosensor.

FIG. 4 is a diagram illustrating an example layout of photoelectric converters in one of pixels according to the first embodiment.

FIG. 5 is a diagram illustrating an example of a circuit configuration of one of first photoelectric converters.

FIG. 6 is a perspective view illustrating an example of a layout of photoelectric converters according to the first embodiment.

FIG. 7 illustrates an example of a change in a cathode voltage of a light-receiving element according to the first embodiment.

FIG. 8 is a graph illustrating an example of a relationship between an excess bias voltage VEX and a PDE of the light-receiving element.

FIG. 9 is a block diagram illustrating a configuration example of a power supply circuit in the first embodiment.

FIG. 10A is a diagram illustrating a characteristic of a dynamic range for one of pixels in a comparative example.

FIG. 10B is a diagram illustrating a characteristic of a dynamic range for one of pixels in the first embodiment.

FIG. 11 is a diagram illustrating an example of a circuit configuration of one of photoelectric converters according to a modification of the first embodiment.

FIG. 12 illustrates an example of a change in an anode voltage of a light-receiving element according to the modification.

FIG. 13 is a diagram illustrating an example layout of photoelectric converters in one of pixels according to a second embodiment.

FIG. 14 is a graph illustrating an example of a relationship between an opening ratio and a PDE of one of the photoelectric converters.

FIG. 15 is a cross-sectional view schematically illustrating a structure of a part of one of pixels in the second embodiment.

FIG. 16A is a diagram illustrating a result of photoelectric conversions at photoelectric converters when a first laser light L is irradiated.

FIG. 16B is a diagram illustrating a result of the photoelectric conversions at the photoelectric converters when a second laser light is irradiated.

FIG. 16C is a diagram illustrating a result of the photoelectric conversions at the photoelectric converters when a third laser light is irradiated.

FIG. 17 is a diagram for explaining an example of a method for collectively adjusting PDEs in a third embodiment.

FIG. 18 is a diagram for explaining another example of a method for collectively adjusting PDEs in the third embodiment.

FIG. 19 is a diagram illustrating an example layout of photoelectric converters in one of pixels according to a fourth embodiment.

FIG. 20 is a cross-sectional view schematically illustrating a structure of a part of one of pixels in the fourth embodiment.

FIG. 21 is a block diagram illustrating an example of a schematic configuration of a vehicle control system.

FIG. 22 is an illustration diagram illustrating an example of installation positions of outside-vehicle information detecting sections and imaging sections.

### MODE FOR CARRYING OUT THE INVENTION

### First Embodiment

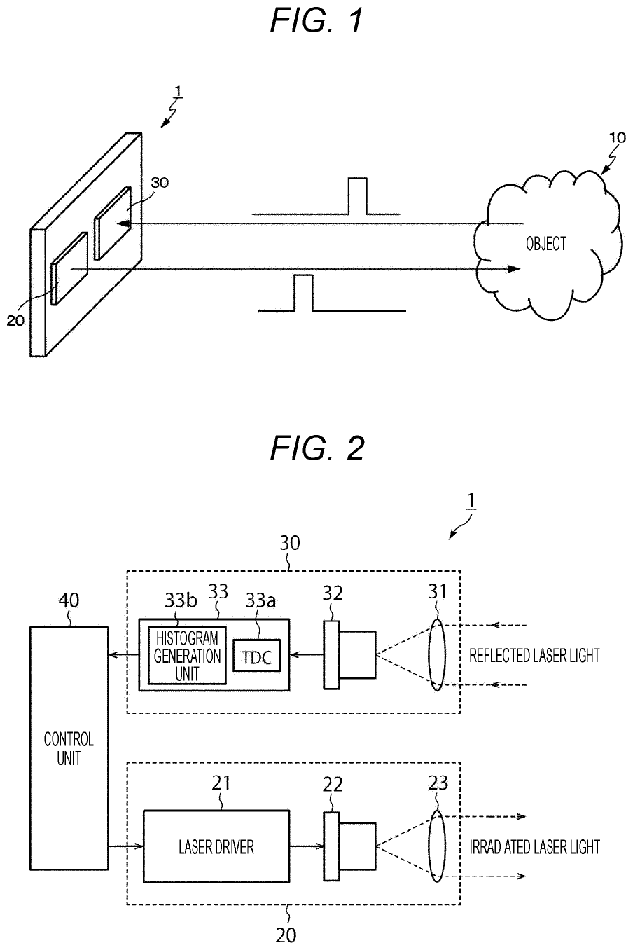

FIG. 1 is a diagram for explaining a distance measuring method by a distance measuring system according to a first embodiment. In the distance measuring system 1 according to the present embodiment, a time of flight (TOF) method is used to measure a distance to an object 10, which is an object to be measured. The TOF method measures time it takes for light (for example, laser light) irradiated toward the object 10 to be reflected by the object 10 and return.

FIG. 2 is a block diagram illustrating an example of a configuration of the distance measuring system 1. In order to achieve distance measurement by the TOF method described above, the distance measuring system 1 according to the present embodiment includes a light source device 20, a photodetection device 30, and a control unit 40.

The light source device 20 includes, for example, a laser driver 21, a laser light source 22, and a diffusion lens 23. The laser driver 21 drives the laser light source 22 under control of the control unit 40. The laser light source 22 includes, for example, a semiconductor laser, and emits laser light by being driven by the laser driver 21. The diffusion lens 23 diffuses the laser light emitted from the laser light source 22, and irradiates the laser light toward the object 10.

The photodetection device 30 includes a light-receiving lens 31, a photosensor 32, and a signal processing circuit 33, and receives, as incident light, reflected laser light that has been irradiated by the light source device 20 and is reflected by the object 10 and returns. The light-receiving lens 31 focuses the reflected laser light from the object 10 on a light-receiving surface of the photosensor 32. Each pixel of the photosensor 32 receives the reflected laser light from the object 10 through the light-receiving lens 31, and performs a photoelectric conversion. The signal processing circuit 33 includes a time to digital converter (TDC) 331 and a histogram generation unit 33b.

The TDC 33A digitally converts time of occurrence of a transition timing of a voltage level of an output signal of the photosensor 32. The histogram generation unit 33b measures the number of acquisitions of a digital value converted by the TDC 33A, that is, the number of reactions of the photosensor 32. Because the digital conversion by the TDC 33A is performed a plurality of times, the histogram generated by the histogram generation unit 33b is obtained by integrating the number of reactions measured a plurality of times by the photosensor 32.

The control unit 40 includes, for example, a central processing unit (CPU) or the like, controls the light source device 20 and the photodetection device 30, and measures a time t from when laser light is irradiated from the light source device 20 toward the object 10 to when the laser light is reflected by the object 10 and returns. A distance L to the object 10 can be determined on the basis of the time t. A method of time measurement includes: starting a timer when pulsed light is irradiated from the light source device 20; stopping the timer when the photodetection device 30 receives the pulsed light; and determining the time t. The time t is determined by detecting a peak of the histogram generated by the histogram generation unit 33b.

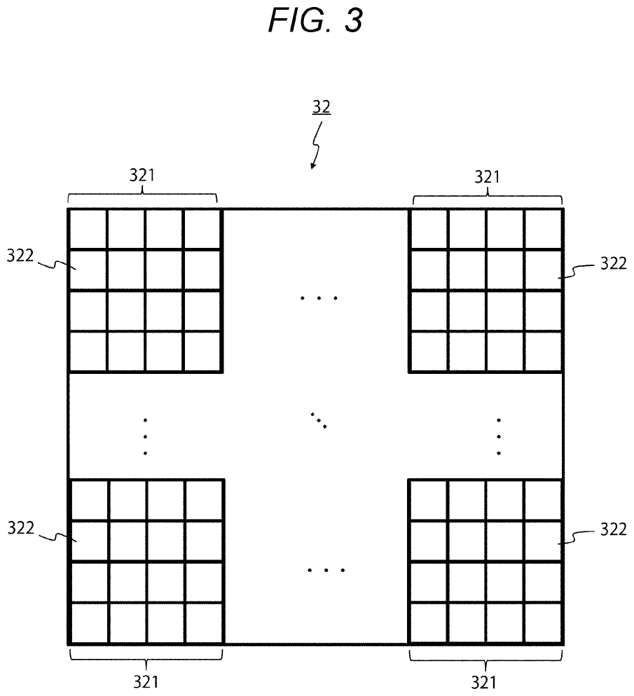

FIG. 3 is a schematic plan view of the photosensor 32. In the present embodiment, the photosensor 32 includes a two-dimensional array sensor (so-called area sensor) in which a plurality of pixels 321 is arranged in a two-dimensional array. Note that the photosensor 32 may include a one-dimensional array sensor (so-called line sensor) in which a plurality of pixels 321 is arranged in a line. Each of the plurality of pixels 321 has a plurality of photoelectric converters 322 arranged in a two-dimensional array. When the light reflected by the object 10 is incident on each of the photoelectric converters 322, each of the photoelectric converters 322 photoelectrically converts the received incident light.

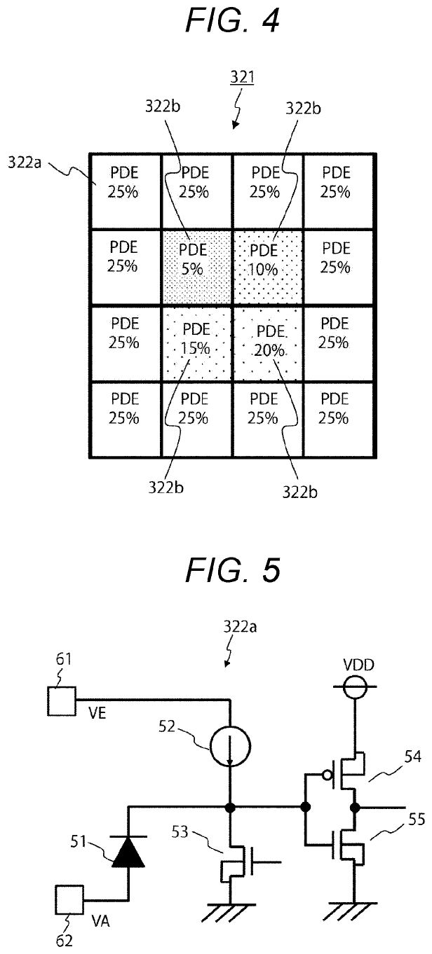

FIG. 4 is a diagram illustrating an example layout of the photoelectric converters 322 in one of pixels according to the first embodiment. In the present embodiment, the plurality of photoelectric converters 322 provided in one of the pixels 321 includes at least one first photoelectric converter 322a and at least one second photoelectric converter 322b that is separate from the first photoelectric converter. The one of the pixels 321 illustrated in FIG. 4 has 12 first photoelectric converters 322a and four second photoelectric converters 322b mixedly arranged. The first photoelectric converters 322a have a photon detection efficiency (PDE) of 25%. On the other hand, the second photoelectric converters 322b have photon detection efficiencies (PDE) of 5% to 20%, which are lower than those for the first photoelectric converters 322a. Here, the PDE is one of indicators of sensitivity of each of the photoelectric converters to incident light, and can be determined, for example, by calculating the number of detected photons with respect to the number of incident photons.

Note that, in FIG. 4, the first photoelectric converters 322a are arranged in an outer peripheral region of the one of the pixels 321, and the second photoelectric converters 322b are arranged in a central region of the one of the pixels 321. However, each arrangement of first and second photoelectric converters 322a and 322b in pixels 321 is not particularly limited.

In addition, in FIG. 4, four second photoelectric converters 322b having different PDEs from each other are arranged. However, because the PDEs of the second photoelectric converters 322b only need to be lower than the PDE of the first photoelectric converters 322a, all the PDEs of the plurality of second photoelectric converters 322b may be a same. Furthermore, the number of second photoelectric converters 322b is also not limited to four. However, as the number of second photoelectric converters 322b increases, the sensitivity of the corresponding one of the pixels 321 decreases. Therefore, it is desirable that the number of second photoelectric converters 322b is smaller than the number of first photoelectric converters 322a.

FIG. 5 is a diagram illustrating an example of a circuit configuration of one of the first photoelectric converters 322a. Note that a circuit configuration of the second photoelectric converters 322b is a same as the circuit configuration of the first photoelectric converters 322a, and therefore is not described.

The one of the first photoelectric converters 322a illustrated in FIG. 5 include: a light-receiving element 51; a current source 52; a quench transistor 53; a transistor 54; and a transistor 55.

The light-receiving element 51 includes, for example, an avalanche photodiode represented by a single photon avalanche diode (SPAD). A cathode of the light-receiving element 51 is connected to a first terminal 61 via the current source 52. A positive voltage VE is applied to the cathode of the light-receiving element 51 via the first terminal 61. An anode of the light-receiving element 51 is connected to a second terminal 62. A negative voltage VA at which avalanche multiplication occurs is applied to the anode of the light-receiving element 51 via the second terminal 62.

The current source 52 is provided between the first terminal 61 and the cathode of the light-receiving element 51. The light-receiving element 51 is charged by the current source 52.

The quench transistor 53 includes, for example, an N-channel MOS transistor. A drain of the quench transistor 53 is connected to the anode of the light-receiving element 51 and the current source 52, and a source is grounded. When a predetermined signal is input to a gate of the quench transistor 53, a cathode voltage of the light-receiving element 51 is forcibly set to a reference voltage of 0 V. In this case, a light detection ability of the light-receiving element 51 is deteriorated. Therefore, it is possible to avoid erroneous detection of an after-pulse or the like in which avalanche multiplication occurs again even though no photons are incident on the light-receiving element 51.

The transistor 54 includes, for example, a P-channel MOS transistor, and the transistor 55 includes, for example, an N-channel MOS transistor. A gate of each transistor is connected to the cathode of the light-receiving element 51. A power supply voltage VDD is applied to a source of the transistor 54. A source of the transistor 55 is grounded. An analog pixel signal generated on the basis of the cathode voltage of the light-receiving element 51 is output from drains of the transistor 54 and the transistor 55.

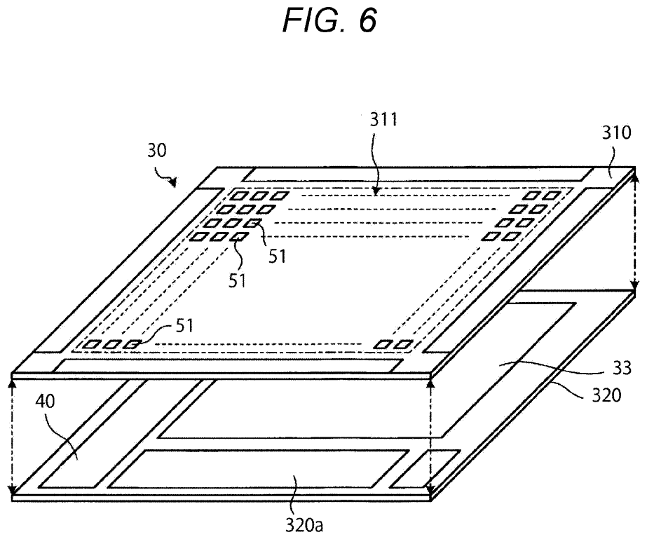

FIG. 6 is a perspective view illustrating an example of a layout of the photoelectric converters 322 according to the present embodiment. The photoelectric converters 322 are arranged separately on a first semiconductor substrate 310 and a second semiconductor substrate 320 stacked on a lower side of the first semiconductor substrate 310. The first semiconductor substrate 310 and the second semiconductor substrate 320 are electrically connected via a connection portion such as a via (VIA), a Cu—Cu bonding, or a bump. That is, the first semiconductor substrate 310 and the second semiconductor substrate 320 are bonded together by any of a chip on chip (CoC) method, a chip on wafer (CoW) method, and a wafer on wafer (WoW) method.

On a light-receiving surface 311 of the first semiconductor substrate 310, the light-receiving element 51 of each of the respective photoelectric converters is arranged in a two-dimensional array. On the other hand, the second semiconductor substrate 320 includes a readout region 320a on a part of a surface facing the first semiconductor substrate 310. Components except the light-receiving element 51, i.e., the current source 52, the quench transistor 53, the transistor 54, and the transistor 55, of each of the photoelectric converters are arranged in the readout region 320a. Furthermore, the signal processing circuit 33 and the control unit 40 described above are arranged around the readout region 320a.

Note that the layout of the first and second photoelectric converters 322a and 322b is not limited to the example illustrated in FIG. 6. For example, the current source 52, the quench transistor 53, the transistor 54, and the transistor 55 may also be arranged on the same first semiconductor substrate 310 as the light-receiving element 51.

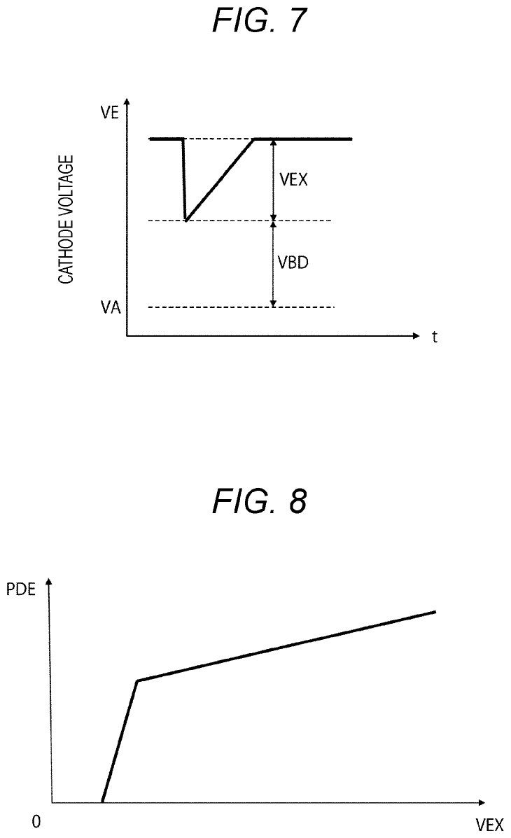

FIG. 7 illustrates an example of a change in the cathode voltage of the light-receiving element 51 according to the first embodiment. In an initial state, the cathode of the light-receiving element 51 is kept at the voltage VE. When the light-receiving element 51 detects photons, an avalanche current flows, and therefore the cathode voltage decreases. When a potential difference between the anode and the cathode of the light-receiving element 51 reaches a breakdown voltage VBD, the avalanche current is shut off. Thereafter, the light-receiving element 51 is charged by the current source 52, and therefore the cathode voltage is recovered to the voltage VE and returns to the initial state again. An excess voltage that exceeds the breakdown voltage VBD is referred to as an excess bias voltage VEX. The excess bias voltage VEX has a correlation with a PDE.

FIG. 8 is a graph illustrating an example of a relationship between the excess bias voltage VEX and the PDE of a light-receiving element 51. In FIG. 8, a horizontal axis shows the excess bias voltage VEX, and a vertical axis shows a PDE.

As illustrated in FIG. 8, the PDE is reduced as the excess bias voltage VEX decreases. Therefore, the PDE can be set by adjusting the excess bias voltage VEX. As illustrated in FIG. 7, the excess bias voltage VEX changes depending on the voltage VE applied to the cathode of the light-receiving element 51 or the voltage VA applied to the anode of the light-receiving element 51.

Fixing the voltage VA while decreasing the voltage VE from, for example, 3 V to 2 V causes the excess bias voltage VEX to become small, and therefore the PDE becomes low. In addition, fixing the voltage VE while increasing the voltage VA, for example, from −20 V to −15 V causes the excess bias voltage VEX to become small. Also, in this case, the PDE becomes low. Thus, the voltage applied to the anode or the cathode of the light-receiving element 51 is adjusted individually, so that the plurality of photoelectric converters 322 having different PDEs can be arranged in the one of the pixels 321.

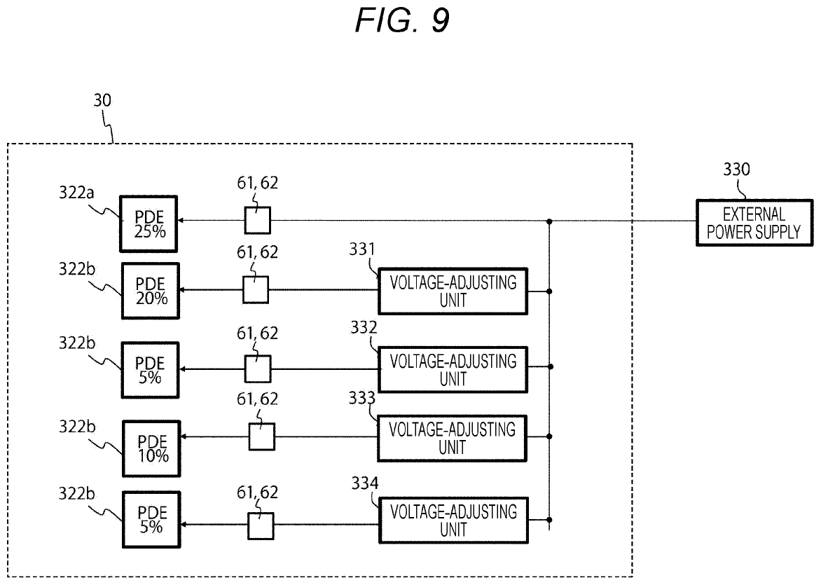

FIG. 9 is a block diagram illustrating a configuration example of a power supply circuit in the present embodiment. In the present embodiment, as illustrated in FIG. 8, the photodetection device 30 further includes voltage-adjusting units 331 to 334. Each of the voltage-adjusting units 331 to 334 is arranged between a first terminal 61 or a second terminal 62 of a corresponding one of the second photoelectric converters 322b and an external power supply 330.

The voltage-adjusting unit 331 adjusts a voltage that has been supplied from the external power supply 330 such that a PDE becomes 20%. The external power supply 330 is a negative power supply that supplies a voltage VA to an anode or a positive power supply that supplies a voltage VE to a cathode of a corresponding light-receiving element 51. In a case where the external power supply 330 is the negative power supply, the voltage-adjusting unit 331 steps up the voltage VA so that the PDE of the corresponding light-receiving element 51 becomes 20%. On the other hand, in a case where the external power supply 330 is the positive power supply, the voltage-adjusting unit 331 steps down the voltage VE so that the PDE of the corresponding one of the second photoelectric converters 322b becomes 20%. Each of the voltage-adjusting unit 332, the voltage-adjusting unit 333, and the voltage-adjusting unit 334, depending on a value of the PDE of the corresponding one of the second photoelectric converters 322b connected thereto, also steps up the corresponding voltage VA or steps down the corresponding voltage VE.

Each voltage-adjusting unit includes a step-up circuit or a step-down circuit depending on a type of the external power supply 330. Each configuration of the step-up circuit and the step-down circuit is not particularly limited, but a smaller number of elements is desirable in order to prevent the photodetection device 30 from growing in size. For example, the step-down circuit may consist of one resistive element.

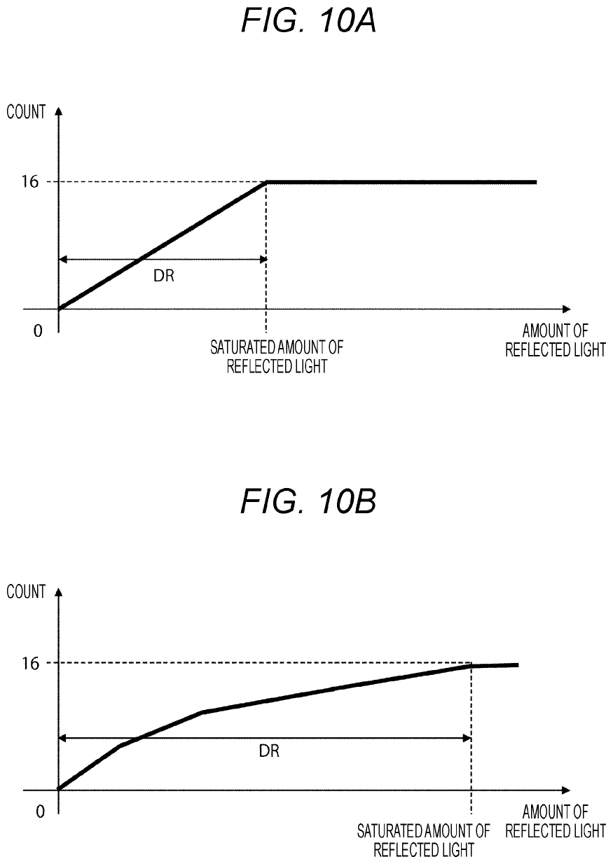

FIG. 10A is a diagram illustrating a characteristic of a dynamic range for one of pixels in a comparative example. FIG. 10B is a diagram illustrating a characteristic of a dynamic range for one of the pixels in the first embodiment. In each of FIG. 10A and FIG. 10B, a horizontal axis shows an amount of reflected light reflected by the object 10. On the other hand, a vertical axis shows the number of photoelectric converters that have detected and photoelectrically converted the reflected light.

The one of the pixels 321 in the comparative example has 16 photoelectric converters 322 arranged in four rows and four columns. In addition, all PDEs of the photoelectric converters 322 are set to 25%. Therefore, as illustrated in FIG. 10A, the number of photoelectric converters 322 that photoelectrically convert the reflected light increases linearly, in other words, in direct proportion until an amount of the reflected light reaches a saturated amount of the reflected light.

Meanwhile, the one of the pixels 321 in the present embodiment has 16 photoelectric converters 322 arranged in four rows and four columns, as in the comparative example. On the other hand, in the present embodiment, PDEs of the photoelectric converters 322 are set within a range of 5% to 25%. That is, the first and second photoelectric converters 322a and 322b having different PDEs are mixedly arranged in the 16 photoelectric converters 322. Therefore, as illustrated in FIG. 10B, the number of photoelectric converters 322 that photoelectrically convert the reflected light increases curvedly until an amount of the reflected light reaches a saturated amount of the reflected light. As a result, the saturated amount of the reflected light in the present embodiment becomes larger than the saturated amount of the reflected light in the comparative example.

Therefore, according to the present embodiment described above, a dynamic range DR can be widened without increasing the number of photoelectric converters 322. Widening the dynamic range DR causes a distance measurable range to be widened, and therefore it becomes possible to improve distance measurement performance.

Also, in the present embodiment, each of the voltage-adjusting units 331 to 334 individually adjusts a PDE of the corresponding one of the photoelectric converters 322. This allows the number and the PDEs of the second photoelectric converters 322b to be set freely.

### Modification

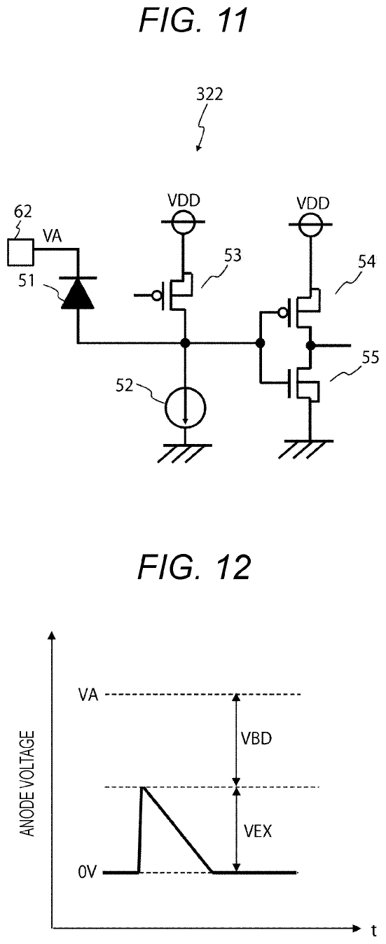

FIG. 11 is a diagram illustrating an example of a circuit configuration of one of photoelectric converters 322 according to a modification of the first embodiment. Same components as those of the first embodiment described above are denoted by same reference numerals, and are not described in detail.

Compared to the first embodiment (see FIG. 5), in the present modification, an anode of a light-receiving element 51 is connected to a current source 52, a drain of a quench transistor 53, and gates of transistors 54 and 55. A positive voltage VA is applied to a cathode of the light-receiving element 51 via a second terminal 62. In addition, the quench transistor 53 includes a P-channel MOS transistor. A power supply voltage VDD is applied to a source of the quench transistor 53. In the present modification, a signal indicating a voltage change in the anode of the light-receiving element 51 is output from the drains of the transistors 54 and 55.

FIG. 12 illustrates an example of a change in an anode voltage of a light-receiving element 51 according to the modification. In an initial state, the anode of the light-receiving element 51 is kept at the reference voltage of 0 V. At this time, the positive voltage VA is applied to the cathode of the light-receiving element 51. Therefore, when the light-receiving element 51 detects light, an avalanche current flows, and as a result, the anode voltage increases.

Thereafter, when a potential difference between the anode and the cathode of the light-receiving element 51 reaches a breakdown voltage VBD, the avalanche current is shut off. Thereafter, the anode voltage is restored to 0 V, and the light-receiving element 51 returns to the initial state again.

In the present modification, the voltage VA corresponds to a voltage obtained by adding an excess bias voltage VEX and the breakdown voltage VBD. As described in the first embodiment, the excess bias voltage VEX has a correlation with a PDE. A graph illustrated in FIG. 12 shows that decreasing the voltage VA shifts the breakdown voltage VBD downward, resulting in the smaller excess bias voltage VEX. Therefore, similarly to the first embodiment, voltage-adjusting units 331 to 334 are used to set respective PDEs.

The voltage-adjusting unit 331 steps down a voltage VA that has been supplied from an external power supply 330 such that a PDE becomes 20%. Each of the voltage-adjusting unit 332, the voltage-adjusting unit 333, and the voltage-adjusting unit 334, depending on a value of a PDE of a corresponding one of the photoelectric converters 322 connected thereto, also steps down a corresponding voltage VA.

Also, in the present modification described above, as in the first embodiment, the plurality of photoelectric converters 322 has different PDEs. This increases a saturated amount of the reflected light, and therefore dynamic range DR can be widened without increasing the number of photoelectric converters 322.

Furthermore, also in the present modification, each of the voltage-adjusting units 331 to 334 individually adjusts a PDE of the corresponding one of the photoelectric converters 322. This allows the number and the PDEs of the second photoelectric converters 322b to be set freely.

### Second Embodiment

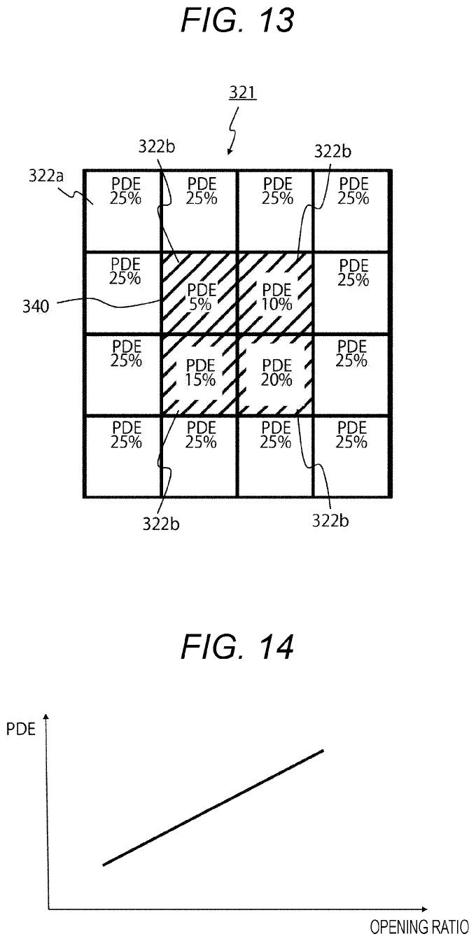

FIG. 13 is a diagram illustrating an example layout of photoelectric converters 322 in one of pixels according to a second embodiment. In the present embodiment, similar to the first embodiment, the photoelectric converters 322 include first and second photoelectric converters 322a and 322b that are separate from the first photoelectric converters. However, in the present embodiment, a method for adjusting the PDEs is different from the first embodiment. In the present embodiment, opening ratios of the second photoelectric converters 322b are smaller than an opening ratio of the first photoelectric converters 322a. Here, an opening ratio is one of indicators indicating a transmissive ratio of incident light.

FIG. 14 is a graph illustrating an example of a relationship between an opening ratio and a PDE of one of the photoelectric converters 322. In FIG. 14, a horizontal axis shows the opening ratio, and a vertical axis shows the PDE. As illustrated in FIG. 14, the PDE is reduced as the opening ratio decreases. Therefore, the PDE can be set by adjusting the opening ratio.

In the present embodiment, as illustrated in FIG. 13, the opening ratio can be adjusted with an area of a light-shielding region including a light-shielding film 340 that blocks incident light. In the present embodiment, causing a light-shielding region of each of the second photoelectric converters 322b wider than a light-shielding region of the first photoelectric converters 322a sets a corresponding one of PDEs of the second photoelectric converters 322b lower than a PDE of the first photoelectric converters 322a. Furthermore, as in the present embodiment, in a case where the second photoelectric converters 322b have a plurality of PDEs that have been set, any of the second photoelectric converters 322b that has a lower PDE has a wider light-shielding region.

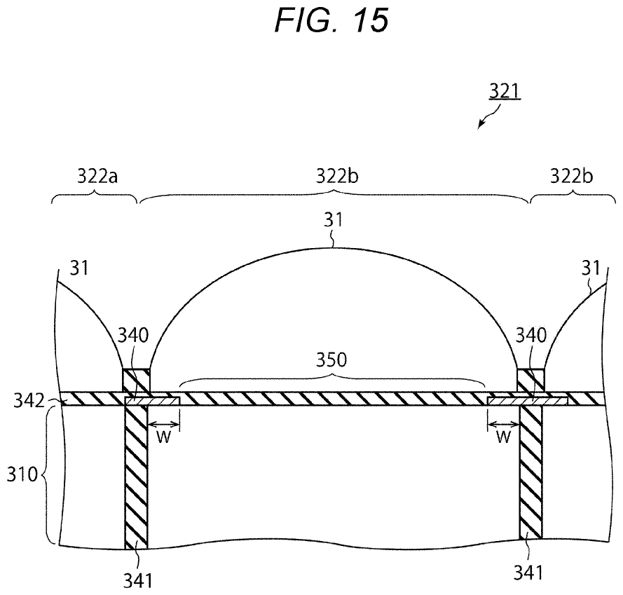

FIG. 15 is a cross-sectional view schematically illustrating a structure of a part of one of pixels 321 in the second embodiment. In the present embodiment, a first semiconductor substrate 310 has a separation film 341 provided for separating the adjacent photoelectric converters from each other. The separation film 341 is formed to include an insulating film made of, for example, silicon oxide (SiO₂) or the like.

The light-shielding film 340 is provided on the separation film 341. The light-shielding film 340 includes a metal having a light blocking effect, such as, for example, tungsten (W) or aluminum (Al). The light-shielding film 340 is covered with an antireflection film 342. The antireflection film 342 prevents light incident on a light-receiving lens 31 from being reflected.

In the present embodiment, as illustrated in FIG. 15, each of the first photoelectric converters 322a has a light-shielding film 340 that does not protrude inwardly (toward a center) from a separation film 341. On the other hand, each of the second photoelectric converters 322b has a light-shielding film 340 that protrudes inwardly (toward a center of that of the second photoelectric converters 322b) from a separation film 341. Therefore, an area of an opening 350 encircled with the light-shielding film 340 is reduced. As a result, an opening ratio of each of the second photoelectric converters 322b is smaller than an opening ratio of the first photoelectric converters 322a.

In addition, the light-shielding region becomes wider, and thus the opening ratio decreases more, as a width w protruding from the separation film 341 becomes longer. Therefore, the light-shielding film 340 is formed such that any of the second photoelectric converters 322b that has a lower PDE has a longer width w described above.

According to the present embodiment described above, the opening ratio of each of the photoelectric converters 322 is adjusted, so that the first and second photoelectric converters 322a and 322b having different PDEs can be formed in the one of the pixels 321. As a result, similar to the first embodiment, a saturated amount of the reflected light increases. Accordingly, a dynamic range DR can be widened without increasing the number of photoelectric converters 322.

In addition, in the present embodiment, the first photoelectric converters 322a and the second photoelectric converters 322b are separately produced in advance depending on a difference in a form of the light-shielding film 340. Therefore, a voltage-adjusting unit described with respect to the first embodiment is not required, resulting in a possible avoidance of growing in size of a device.

### Third Embodiment

A third embodiment will be described. Same components as those of the first embodiment described above are denoted by same reference numerals, and are not described in detail. In the present embodiment, PDEs are collectively changed in a stepwise manner depending on a result of photoelectric conversions at a plurality of photoelectric converters 322 arranged in one of pixels 321. Hereinafter, an operation of a distance measuring system according to the present embodiment will be described.

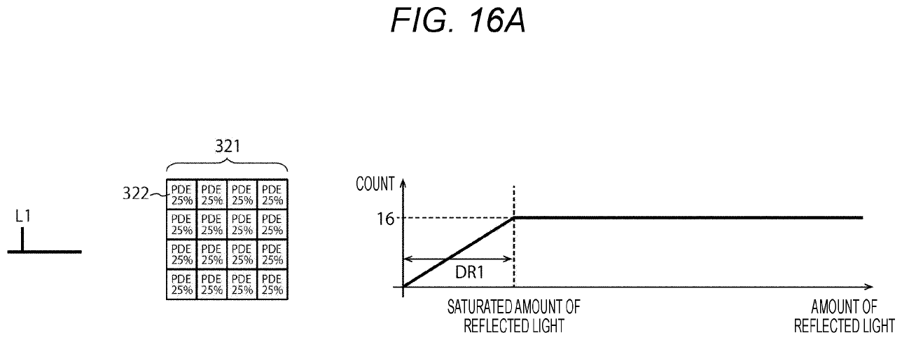

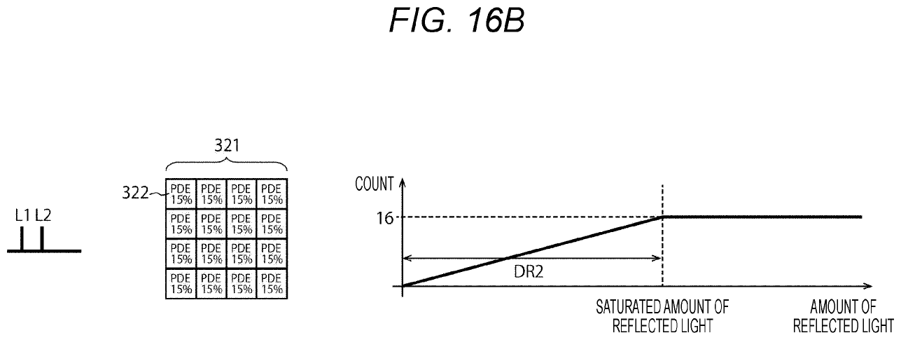

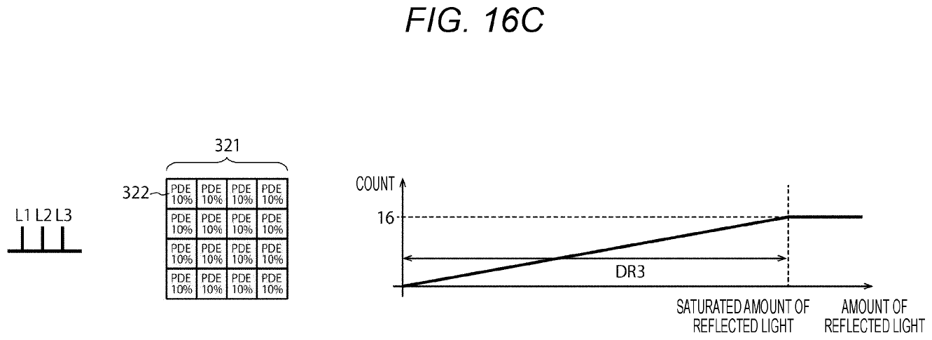

FIG. 16A is a diagram illustrating a result of the photoelectric conversions at the photoelectric converters 322 when a first laser light L1 is irradiated. First, when the laser light source 22 (see FIG. 2) irradiates the object 10 with the laser light L1, the light reflected by the object 10 enters the plurality of photoelectric converters 322 arranged in the one of the pixels 321. At this time, the PDEs of all the photoelectric converters 322 are set to, for example, 25%.

Each of the photoelectric converters 322 outputs a signal indicating whether or not the photoelectric conversion has been performed (whether or not incident light has been detected) to the signal processing circuit 33 (see FIG. 2). In the signal processing circuit 33, the TDC 33A and the histogram generation unit 33b measure the number of photoelectric converters 322 that have photoelectrically converted the incident light, that is, the number of photoelectric converters 322 that have detected the incident light, and output a measurement result to the control unit 40 (see FIG. 2).

The control unit 40 determines whether or not each of the pixels 321 is saturated on the basis of the measurement result of the signal processing circuit 33. The control unit 40 determines each of the pixels 321 in which all the photoelectric converters 322 have photoelectrically converted the incident light is saturated, and determines that the other pixels are not saturated.

The saturated one of the pixels 321 has the photoelectric converters 322 of which the PDEs may be set higher than necessary for the reflected light. In this case, a saturated amount of the reflected light becomes small, resulting in a reduced dynamic range. Therefore, in the present embodiment, the control unit 40 collectively decreases the PDEs of all the photoelectric converters 322 in the one of the pixels 321. For example, the PDEs are reset to 15%, which is lower than 25%. As a result, the dynamic range of the one of the pixels 321 is widened.

On the other hand, the PDEs of the unsaturated one of the pixels 321 are considered appropriate. Therefore, the control unit 40 maintains the PDEs of all the photoelectric converters 322 in the one of the pixels 321.

FIG. 16B is a diagram illustrating a result of the photoelectric conversions at the photoelectric converters 322 when a second laser light L2 is irradiated. In a case where the control unit 40 decreases the PDEs of the photoelectric converters 322, the laser light source 22 irradiates the object 10 with a second laser light L2. An intensity of the laser light L2 is a same as an intensity of the first laser light L1.

The light reflected by the object 10 enters the plurality of photoelectric converters 322 arranged in the one of the pixels 321. Each of the photoelectric converters 322 again outputs a signal indicating whether or not the photoelectric conversion has been performed to the signal processing circuit 33. The signal processing circuit 33 also again measures the number of photoelectric converters 322 that have photoelectrically converted the incident light, and outputs a measurement result to the control unit 40. The control unit 40 again determines whether or not each of the pixels 321 is saturated on the basis of the measurement result of the signal processing circuit 33.

The dynamic range of the one of the pixels 321 widens from a dynamic range DR1 (see FIG. 16A) to a dynamic range DR2 (see FIG. 16B) between before and after the irradiation with the second laser light L2. A still saturated one of the pixels 321 has the photoelectric converters 322 of which the PDEs may still be set higher than necessary. Therefore, in this case, the control unit 40 further collectively decreases the PDEs of all the photoelectric converters 322 in the one of the pixels 321. For example, the PDEs are reset to 10%, which is lower than 15%. The dynamic range of the one of the pixels 321 is further widened.

On the other hand, the PDEs of the unsaturated one of the pixels 321 are considered appropriate. Therefore, the control unit 40 maintains the PDEs of all the photoelectric converters 322 in the one of the pixels 321.

FIG. 16C is a diagram illustrating a result of the photoelectric conversions at the photoelectric converters 322 when a third laser light L3 is irradiated. In a case where the control unit 40 further decreases the PDEs of the photoelectric converters 322, the laser light source 22 irradiates the object 10 with a third laser light L3. An intensity of the laser light L3 is a same as an intensity of the first laser light L1.

The light reflected by the object 10 enters the plurality of photoelectric converters 322 arranged in the one of the pixels 321. Each of the photoelectric converters 322 again outputs a signal indicating whether or not the photoelectric conversion has been performed to the signal processing circuit 33. The signal processing circuit 33 also again measures the number of photoelectric converters 322 that have photoelectrically converted the incident light, and outputs a measurement result to the control unit 40. The control unit 40 again determines whether or not each of the pixels 321 is saturated on the basis of the measurement result of the signal processing circuit 33.

The dynamic range of the one of the pixels 321 further widens from a dynamic range DR2 (see FIG. 16B) to a dynamic range DR3 (see FIG. 16C) between before and after the irradiation with the third laser light L3. A still saturated one of the pixels 321 has the photoelectric converters 322 of which the PDEs may still be set higher than necessary. Therefore, in this case, the control unit 40 further collectively decreases the PDEs of all the photoelectric converters 322 in the one of the pixels 321.

On the other hand, the PDEs of the unsaturated one of the pixels 321 are considered appropriate. Therefore, the control unit 40 maintains the PDEs of all the photoelectric converters 322 in the one of the pixels 321.

Thus, in the present embodiment, the PDEs of all the photoelectric converters 322 in the one of the pixels 321 are collectively adjusted in conjunction with the irradiation of the laser light until the one of the pixels 321 becomes unsaturated. Hereinafter, a method for collectively adjusting PDEs according to the present embodiment will be described.

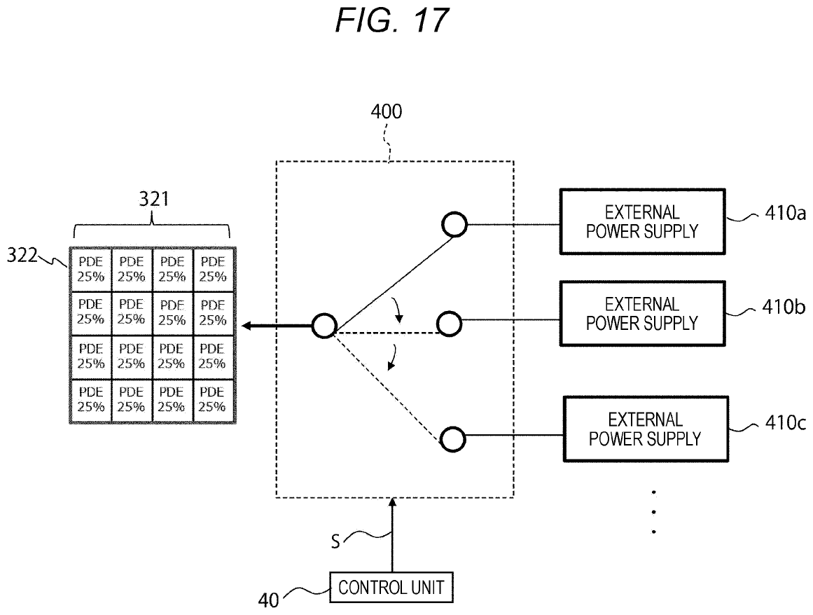

FIG. 17 is a diagram for explaining an example of a method for collectively adjusting PDEs in a third embodiment. The method shown in FIG. 17 uses a switch 400 to adjust the PDEs.

One end of the switch 400 is connected to each of a plurality of external power supplies 410a to 410c. Output voltages of the external power supplies 410a to 410c are different from each other. The other end of the switch 400 is connected to each of the plurality of photoelectric converters 322. An output voltage from the external power supplies 410a to 410c is applied to an anode or a cathode of each light-receiving element 51 via the switch 400. The switch 400 switches a voltage to be applied to a light-receiving element 51 of each of the photoelectric converters 322 from an output voltage of an external power supply of the external power supplies 410a to 410c to an output voltage of another external power supply on the basis of a control signal S from the control unit 40.

For example, let's suppose that each of the photoelectric converters 322 has the circuit configuration illustrated in FIG. 5, and the first laser light L1 is irradiated while the voltage is applied from the external power supply 410a to the cathode of the light-receiving element 51. In a case where it is determined that one of the resulting pixels 321 is saturated, the switch 400 switches the connection of the photoelectric converters 322 from the external power supply 410a to the external power supply 410b. The output voltage of the external power supply 410b is lower than the output voltage of the external power supply 410a. Therefore, the voltage applied to the cathode of the light-receiving element 51 decreases. In this case, an excess bias voltage VEX also decreases, so that the PDEs decrease.

In addition, let's suppose that it is determined that one of the pixels 321 is saturated when the second laser light L2 is irradiated while the voltage is applied from the external power supply 410b to the cathode of the light-receiving element 51. In this case, the switch 400 switches the connection of the photoelectric converters 322 from the external power supply 410b to the external power supply 410c. The output voltage of the external power supply 410c is lower than the output voltage of the external power supply 410b. Therefore, the voltage applied to the cathode of the light-receiving element 51 further decreases, so that the PDEs also further decrease. Note that a method for adjusting the PDEs is not limited to the method illustrated in FIG. 17.

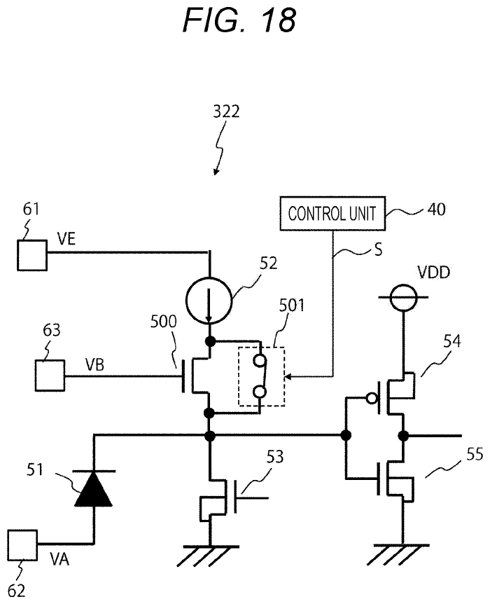

FIG. 18 is a diagram for explaining another example of a method for collectively adjusting PDEs in the third embodiment. The method shown in FIG. 18 can adjust the PDEs in two stages by using a transistor 500 and a switch 501.

The transistor 500 is, for example, an N-channel MOS transistor, and is provided between a cathode of a light-receiving element 51 and a current source 52. A drain of the transistor 500 is connected to the current source 52, and a source is connected to the cathode of the light-receiving element 51. A voltage VB is applied to the gate of the transistor 500. The switch 501 is connected in parallel to the transistor 500. The switch 501 is turned on and off on the basis of a control signal S input from a control unit 40.

When the photoelectric converters 322 are in an initial state, the switch 501 is turned on. In this case, the excess bias voltage VEX is a voltage VE applied to the cathode of the light-receiving element via a first terminal 61. In a case where, while the switch 501 is turned on, it is determined that a corresponding one of the pixels 321 is saturated, the switch 501 is turned from on to off on the basis of the control signal S from the control unit 40.

When the switch 501 is turned off, the excess bias voltage VEX becomes a voltage obtained by subtracting a voltage VGS from the voltage VB. Here, the voltage VB is a voltage applied to the gate of the transistor 500 as described above. The voltage VGS is a voltage between the gate and the source of the transistor 500. The voltage obtained by subtracting the voltage VGS from the voltage VB is lower than the voltage VE. Therefore, the excess bias voltage VEX decreases compared to the case where the switch 501 is turned on. As a result, the PDEs also decrease.

Note that, in a case where the photoelectric converters 322 have the circuit configuration illustrated in FIG. 11, the transistor 500 and the switch 501 are provided between an anode of the light-receiving element and the current source 52. Also, in this case, the excess bias voltage VEX decreases by turning the switch 501 from on to off, so that the PDEs can be decreased.

In the present embodiment described above, the control unit 40 determines whether or not each of the pixels 321 is saturated every time a laser light is irradiated. In a case where it is determined that one of the resulting pixels 321 is saturated, the PDEs of all the photoelectric converters 322 in the one of the pixels 321 are collectively decreased. Actively changing the PDEs in this manner allows the dynamic range DR to be widened without increasing the number of photoelectric converters 322.

### Fourth Embodiment

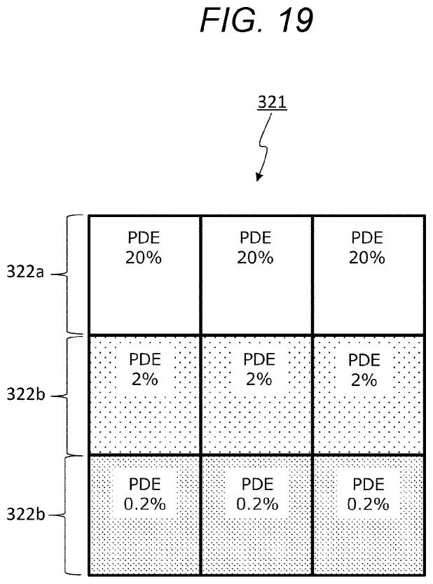

FIG. 19 is a diagram illustrating an example layout of photoelectric converters 322 in one of pixels according to a fourth embodiment. In the present embodiment, similar to the second embodiment, the photoelectric converters 322 include first and second photoelectric converters 322a and 322b that are separate from the first photoelectric converters. However, in the present embodiment, a PDE of the first photoelectric converters 322a is set to 20%, while PDEs of the second photoelectric converters 322b are set to 2% and 0.2%. Therefore, a difference in PDE between the first photoelectric converters 322a and the second photoelectric converters 322b is 10 times or more. Furthermore, in the present embodiment, a difference in PDE among the second photoelectric converters 322b is also 10 times or more.

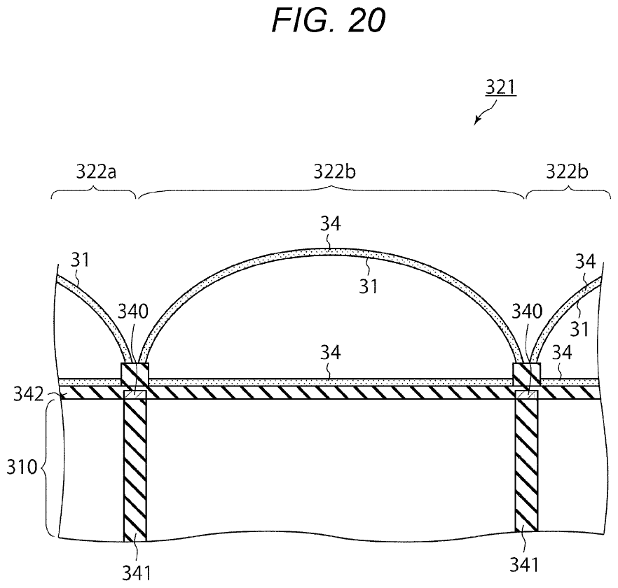

FIG. 20 is a cross-sectional view schematically illustrating a structure of a part of one of the pixels 321 in the fourth embodiment. In FIG. 20, components similar to those of the second embodiment illustrated in FIG. 15 are denoted by same reference numerals, and are not described redundantly.

In the present embodiment, an optical filter 34 is provided on a surface of a light-receiving lens 31. The optical filter 34 includes a neutral density (ND) filter, which attenuates incident light. In FIG. 20, the optical filter 34 is attached to an upper surface and a bottom surface of the light-receiving lens 31, but a location where the optical filter 34 is attached is adjusted appropriately depending on a set value of a corresponding one of PDEs. For example, the first photoelectric converters 322a may have an optical filter 34 provided only on an upper surface of a light-receiving lens 31, and the second photoelectric converters 322b may have an optical filter 34 provided on an upper surface and a bottom surface of a light-receiving lens 31. That is, the optical filter 34 may be provided on at least one of the upper surface or the bottom surface of the light-receiving lens depending on the set value of the corresponding one of the PDEs.

Furthermore, a transmittance of the optical filter 34 may be changed depending on the set value of the corresponding one of the PDEs. For example, a transmittance of an optical filter 34 of the second photoelectric converters 322b that has a PDE set to 2% is higher than a transmittance of an optical filter 34 of the second photoelectric converters 322b that has a PDE set to 0.2%. This allows the second photoelectric converters 322b to form photoelectric conversions having different PDEs.

Note that, in FIG. 20, an optical filter 34 is also provided on a light-receiving lens 31 of the first photoelectric converters 322a. However, an optical filter 34 may be provided only on a light-receiving lens 31 of the second photoelectric converters 322b. Also, in this case, a PDE of the first photoelectric converters 322a can be set higher than the PDEs of the second photoelectric converters 322b.

According to the present embodiment described above, by means of each optical filter 34, the first and second photoelectric converters 322a and 322b having different PDEs can be formed in the one of the pixels 321. As a result, similar to the first embodiment, a saturated amount of the reflected light increases. Accordingly, a dynamic range DR can be widened without increasing the number of photoelectric converters 322.

In particular, in the present embodiment, the difference in PDE between the first photoelectric converters 322a and the second photoelectric converters 322b is 10 times or more. Thus, a dynamic range DR can be further widened compared to the other embodiments described above.

### <Practical Application Example to Mobile Body>

Technology (present technology) according to the present disclosure is applicable to various products. For example, the technology according to the present disclosure may be achieved in a form of an apparatus to be mounted to a mobile body of any kind such as an automobile, an electric vehicle, a hybrid electric vehicle, a motorcycle, a bicycle, a personal mobility, an airplane, a drone, a vessel, and a robot.

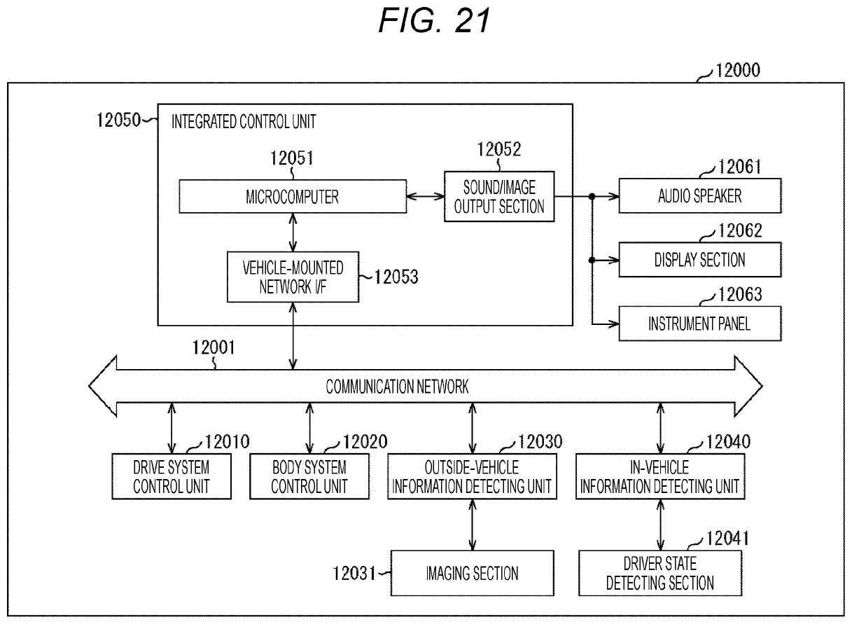

FIG. 21 is a block diagram illustrating an example of schematic configuration of a vehicle control system as an example of a mobile body control system to which the technology according to the present disclosure can be applied.

The vehicle control system 12000 includes a plurality of electronic control units connected to each other via a communication network 12001. In the example illustrated in FIG. 21, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating a driving force of a vehicle, such as a steering mechanism internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound or an image to an output device capable of visually or auditorily notifying information to an occupant of the vehicle or the outside of the vehicle. In an example in FIG. 21, an audio speaker 12061, a display section 12062, and an instrument panel 12063 are illustrated as the output device. The display section 12062 may, for example, include at least one of an on-board display or a head-up display.

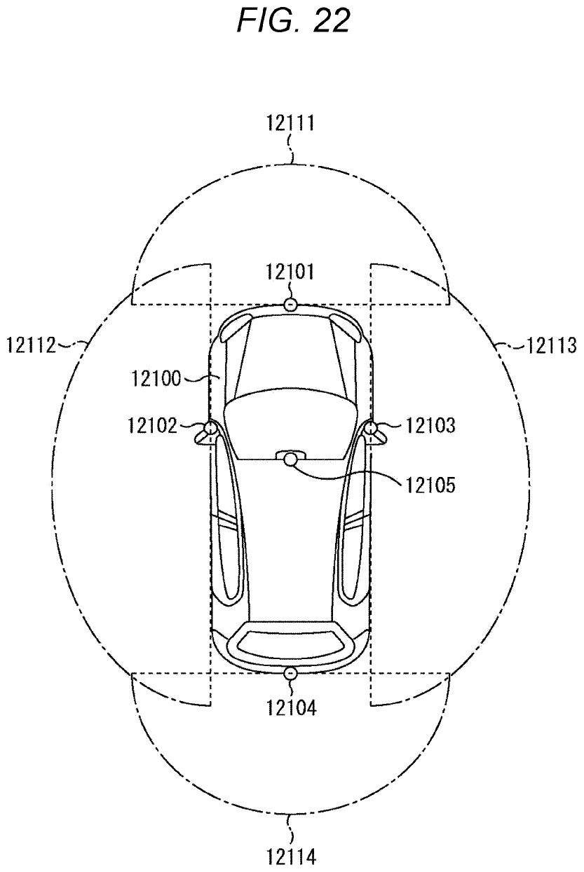

FIG. 22 is a diagram illustrating an example of an installation position of the imaging section 12031.

In FIG. 22, the imaging section 12031 includes imaging sections 12101, 12102, 12103, 12104, and 12105.

The imaging sections 12101, 12102, 12103, 12104, and 12105 are, for example, provided at positions on a front nose, sideview mirrors, a rear bumper, and a hatchback door of the vehicle 12100 as well as a position on an upper portion of a windshield within the interior of the vehicle and the like. The imaging section 12101 provided at the front nose and the imaging section 12105 provided at the upper portion of the windshield within the interior of the vehicle acquire mainly an image in front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that, FIG. 22 illustrates an example of photographing ranges of the imaging sections 12101 to 12104. An imaging range 12111 indicates the imaging range of the imaging section 12101 provided at the front nose. Imaging ranges 12112 and 12113 respectively indicate the imaging ranges of the imaging sections 12102 and 12103 provided at the sideview mirrors. An imaging range 12114 indicates the imaging range of the imaging section 12104 provided at the rear bumper or the hatchback door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to, for example, the imaging section 12031 of the configurations described above. Specifically, the photodetection device 30 can be applied to the imaging section 12031. By applying the technology according to the present disclosure, a captured image with higher distance measurement performance can be obtained, whereby safety can be improved.

Note that the present technology can have the following configurations.

(1) A photodetection device including a plurality of photoelectric converters arranged in one of pixels and configured to photoelectrically convert incident light, in which
the plurality of photoelectric converters includes: at least one first photoelectric converter; and
at least one second photoelectric converter having a lower sensitivity to the incident light than the first photoelectric converter.

(2) The photodetection device according to (1), in which each sensitivity is different from others among the plurality of second photoelectric converters.

(3) The photodetection device according to (1) or (2), in which a number of the second photoelectric converters is smaller than a number of the first photoelectric converters.

(4) The photodetection device according to any one of (1) to (3), in which
each of the first photoelectric converters includes a first avalanche photodiode and
each of the second photoelectric converters includes a second avalanche photodiode.

(5) The photodetection device according to (4), in which a first voltage applied to the first avalanche photodiode is different from a second voltage applied to the second avalanche photodiode.

(6) The photodetection device according to (5), in which in a case where the first voltage is applied to a cathode of the first avalanche photodiode and the second voltage is applied to a cathode of the second avalanche photodiode, the second voltage is lower than the first voltage.

(7) The photodetection device according to (5), in which in a case where the first voltage is applied to an anode of the first avalanche photodiode and the second voltage is applied to an anode of the second avalanche photodiode, the second voltage is higher than the first voltage.

(8) The photodetection device according to any one of (5) to (8), further including a voltage-adjusting unit that is configured to adjust the first voltage to the second voltage.

(9) The photodetection device according to any one of (1) to (3), in which opening ratios of the second photoelectric converters are smaller than an opening ratio of the first photoelectric converters.

(10) The photodetection device according to (9), in which a light-shielding region from the incident light in each of the second photoelectric converters is wider than a light-shielding region from the incident light in the first photoelectric converters.

(11) The photodetection device according to (10), further including a light-shielding film provided in the light-shielding region.

(12) A photodetection device including
a plurality of photoelectric converters arranged in one of pixels and configured to photoelectrically convert incident light, in which
sensitivities of the plurality of photoelectric converters to the incident light are configured to be collectively decreased in a stepwise manner depending on a result of photoelectric conversions at the plurality of photoelectric converters.

(13) The photodetection device according to (12), in which in a case where all of the plurality of photoelectric converters photoelectrically convert the incident light, the sensitivities are configured to be collectively decreased in a stepwise manner.

(14) The photodetection device according to (12) or (13), further including a switch connected to a plurality of external power supplies having different output voltages from each other, in which
the switch is configured to switch a voltage to be applied to the plurality of photoelectric converters from an output voltage of an external power supply of the plurality of external power supplies to an output voltage of another external power supply depending on a result of photoelectric conversions at the plurality of photoelectric converters.

(15) The photodetection device according to (12) or (13), in which each of the plurality of photoelectric converters includes an avalanche photodiode, a transistor connected to the avalanche photodiode, and a switch connected in parallel to the transistor, in which
the switch is configured to be turned on and off depending on a result of a photoelectric conversion at the avalanche photodiode.

(16) The photodetection device according to (1) or (2), further including:
a light-receiving lens that focuses the incident light on the plurality of photoelectric converters; and
an optical film that is provided on a surface of the light-receiving lens and is configured to attenuate the incident light depending on a set value of the sensitivity.

(17) The photodetection device according to (16) or (17), in which the sensitivity of the first photoelectric converters is 10 times or more higher than the sensitivities of the second photoelectric converters.

(18) A distance measuring system including:
a photodetection device including a plurality of photoelectric converters arranged in one of pixels and configured to photoelectrically convert incident light, in which the plurality of photoelectric converters includes: at least one first photoelectric converter; and at least one second photoelectric converter having a lower sensitivity to the incident light than the first photoelectric converter; and
a signal processing circuit that processes an output signal of the photodetection device.

(19) A distance measuring system including:
a photodetection device including a plurality of photoelectric converters arranged in one of pixels and configured to photoelectrically convert incident light, in which sensitivities of the plurality of photoelectric converters to the incident light are configured to be collectively decreased in a stepwise manner depending on a result of photoelectric conversions at the plurality of photoelectric converters; and
a signal processing circuit that processes an output signal of the photodetection device.

### REFERENCE SIGNS LIST

1 Distance measuring system
30 Photodetection device
33 Signal processing circuit
51 Light-receiving element
321 Pixel
322 Photoelectric converter
322a First photoelectric converter
322b Second photoelectric converter
331 to 334 Voltage-adjusting unit
340 Light-shielding film
400 Switch
500 Transistor
501 Switch

1. A photodetection device comprising
a plurality of photoelectric converters arranged in one of pixels and configured to photoelectrically convert incident light, wherein
the plurality of photoelectric converters comprises: at least one first photoelectric converter; and at least one second photoelectric converter having a lower sensitivity to the incident light than the first photoelectric converter.

2. The photodetection device according to claim 1, wherein each sensitivity is different from others among the plurality of second photoelectric converters.

3. The photodetection device according to claim 1, wherein a number of the second photoelectric converters is smaller than a number of the first photoelectric converters.

4. The photodetection device according to claim 1, wherein
each of the first photoelectric converters comprises a first avalanche photodiode and
each of the second photoelectric converters comprises a second avalanche photodiode.

5. The photodetection device according to claim 4, wherein a first voltage applied to the first avalanche photodiode is different from a second voltage applied to the second avalanche photodiode.

6. The photodetection device according to claim 5, wherein in a case where the first voltage is applied to a cathode of the first avalanche photodiode and the second voltage is applied to a cathode of the second avalanche photodiode, the second voltage is lower than the first voltage.

7. The photodetection device according to claim 5, wherein in a case where the first voltage is applied to an anode of the first avalanche photodiode and the second voltage is applied to an anode of the second avalanche photodiode, the second voltage is higher than the first voltage.

8. The photodetection device according to claim 5, further comprising a voltage-adjusting unit that is configured to adjust the first voltage to the second voltage.

9. The photodetection device according to claim 1, wherein opening ratios of the second photoelectric converters are smaller than an opening ratio of the first photoelectric converters.

10. The photodetection device according to claim 9, wherein a light-shielding region from the incident light in each of the second photoelectric converters is wider than a light-shielding region from the incident light in the first photoelectric converters.

11. The photodetection device according to claim 10, further comprising a light-shielding film provided in the light-shielding region.

12. A photodetection device comprising
a plurality of photoelectric converters arranged in one of pixels and configured to photoelectrically convert incident light, wherein
sensitivities of the plurality of photoelectric converters to the incident light are configured to be collectively decreased in a stepwise manner depending on a result of photoelectric conversions at the plurality of photoelectric converters.

13. The photodetection device according to claim 12, wherein in a case where all of the plurality of photoelectric converters photoelectrically convert the incident light, the sensitivities are configured to be collectively decreased in a stepwise manner.

14. The photodetection device according to claim 12, further comprising
a switch connected to a plurality of external power supplies having different output voltages from each other, wherein
the switch is configured to switch a voltage to be applied to the plurality of photoelectric converters from an output voltage of an external power supply of the plurality of external power supplies to an output voltage of another external power supply depending on a result of photoelectric conversions at the plurality of photoelectric converters.

15. The photodetection device according to claim 12, wherein
each of the plurality of photoelectric converters comprises an avalanche photodiode, a transistor connected to the avalanche photodiode, and a switch connected in parallel to the transistor, wherein
the switch is configured to be turned on and off depending on a result of a photoelectric conversion at the avalanche photodiode.

16. The photodetection device according to claim 1, further comprising:
a light-receiving lens that focuses the incident light on the plurality of photoelectric converters; and
an optical film that is provided on a surface of the light-receiving lens and is configured to attenuate the incident light depending on a set value of the sensitivity.

17. The photodetection device according to claim 16, wherein the sensitivity of the first photoelectric converters is 10 times or more higher than the sensitivities of the second photoelectric converters.

18. A distance measuring system comprising:
a photodetection device comprising a plurality of photoelectric converters arranged in one of pixels and configured to photoelectrically convert incident light, wherein the plurality of photoelectric converters comprises: at least one first photoelectric converter; and at least one second photoelectric converter having a lower sensitivity to the incident light than the first photoelectric converter; and
a signal processing circuit that processes an output signal of the photodetection device.

19. A distance measuring system comprising:
a photodetection device comprising a plurality of photoelectric converters arranged in one of pixels and configured to photoelectrically convert incident light, wherein sensitivities of the plurality of photoelectric converters to the incident light are configured to be collectively decreased in a stepwise manner depending on a result of photoelectric conversions at the plurality of photoelectric converters; and
a signal processing circuit that processes an output signal of the photodetection device.
